(19) United States
(12) Patent Application Publication
(10) Pub. No.: US 2011/0141036 A1
(43) Pub. Date: Jun. 16, 2011

(54) SUBSTRATE FOR TOUCH PANEL AND TOUCH PANEL

(76) Inventor: Jane Hsu, Guishan Township (TW)

(21) Appl. No.: 12/752,657

(22) Filed: Apr. 1, 2010

(30) Foreign Application Priority Data
Dec. 11, 2009 (TW) 098223216

(51) Int. Cl. G06F 3/041; H05K 1/00; H05K 1/09

(52) U.S. Cl. 345/173; 174/250; 174/257

(57) ABSTRACT

A substrate for a touch panel has a conductive layer, a wire-arranged area and multiple wires. The wire-arranged area is arranged on the substrate surrounding the conductive layer and has a rough surface. The wires are formed on the rough surface of the wire-arranged area and each wire has a rough bottom corresponding to the rough surface of the wire-arranged area. The rough surface of the wire-arranged area securely engages the wires and increases thickness of each wire, which decreases a width of each wire and reduces resistance. A touch panel with the substrate of the present invention has improved quality.

### BACKGROUND OF THE INVENTION

1. Field of Invention

The present invention is related to a substrate for a touch panel, and more particularly to a substrate for a touch panel, which provides large friction for firmly engaging with conductors with increased thickness and lowered resistivity and improving yield of the touch panel.

2. Description of the Related Art

Minimization of electronic devices by decreased dimensions with increased function, simplified operation or the like all drive sales. Touch panel technology has been applied to electronic devices to replace keyboards and keypads. In recent years, touch panels have been used for palm digital assistant (PDA), cell phones, tablet computers and the like.

Conventional touch panels include resistive touch panels, capacitive touch panels, acoustic wave touch panels and optical touch panels. Capacitive touch panels are then grouped into surface resistive touch panels (single-touch) and projected capacitive touch panel (multi-touch).

A conventional multi-touch panel comprises at least one substrate. Each substrate has an indium tin oxide (ITO) conductive layer, a wire-arranged area and multiple wires. The ITO conductive layer is formed on the substrate. The wire-arranged area is arranged on the substrate surrounding the ITO conductive layer. The wires are sputtered on the wire-arranged area and electrically connect the ITO conductive layer. All wires are connected to a wiring board.

In order to maintain sensitivity and quick response, a number of points of contact of the ITO conductive layer is increased, then an amount of the wires is also increased. Therefore, the ITO conductive layer has to be enlarged while the substrate has the same or smaller size to conform with demands for the electronic devices. Therefore, a width of wire has to be minimized to allow arrangement in a limited space.

However, the wires are sputtered on the substrate, such that reducing the width of each wire is difficult. Furthermore, the wires may have uneven width, which generates unsteady resistance or even increased resistance. Moreover, because the substrate of the multi-touch panel is made of glass and is flat and very smooth, the wires cannot be attached securely to the substrate. If the width of the wire is reduced, the wire may be break or detached from the substrate due to a smaller contact area between each wire and the substrate.

To overcome the shortcomings, the present invention provides a substrate for a touch panel to mitigate or obviate the aforementioned.

### SUMMARY OF THE INVENTION

The primary objective of the present invention is to provide a substrate for a touch panel, which provides large friction for firmly engaging with conductors with increased thickness and lowered resistivity and improving yield of the touch panel.

To achieve the objective, a substrate for a touch panel in accordance with the present invention comprises a conductive layer, a wire-arranged area and multiple wires. The wire-arranged area is arranged on the substrate surrounding the conductive layer and has a rough surface. The wires are formed on the rough surface of the wire-arranged area and each wire has a rough bottom corresponding to the rough surface of the wire-arranged area.

The rough surface of the wire-arranged area securely engages the wires and increases thickness of each wire, which decreases a width of each wire and reduces resistance. A touch panel with the substrate of the present invention has improved quality.

Other objectives, advantages and novel features of the invention will become more apparent from the following detailed description when taken in conjunction with the accompanying drawings.

### BRIEF DESCRIPTION OF THE DRAWINGS

FIG. 1 is a top view of a substrate for a touch panel in accordance with the present invention;

FIG. 2 is a partial side view of the substrate in FIG. 1; and

FIG. 3 is a partially enlarged side view of the substrate in FIG. 2.

### DETAILED DESCRIPTION OF THE INVENTION

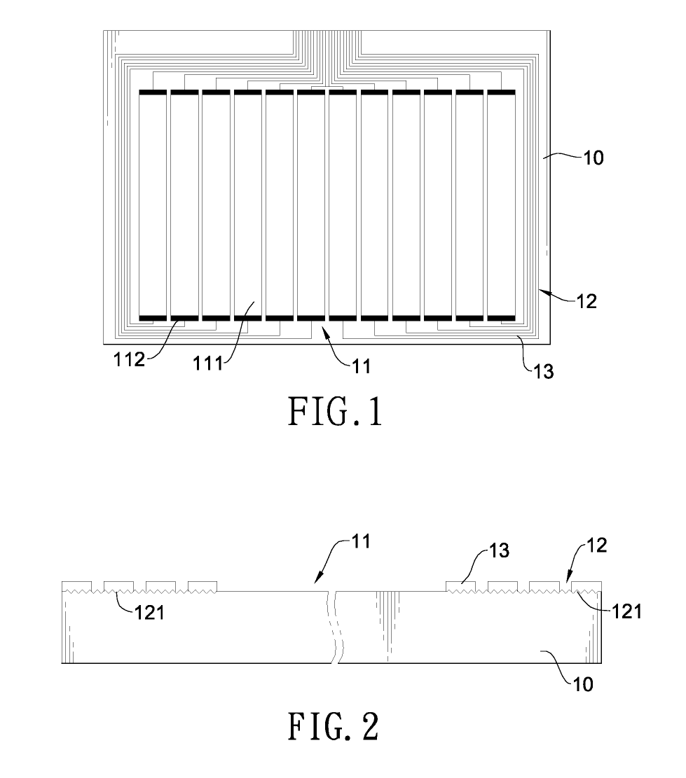

With reference to FIG. 1, a touch panel in accordance with the present invention has at least one substrate (10). In a preferred embodiment, the touch panel is a matrix touch panel. Each substrate (10) for the touch panel in accordance with the present invention has a conductive layer (11), a wire-arranged area (12) and multiple wires (13).

The conductive layer (11) may be made of indium tin oxide (ITO). The conductive layer (11) has multiple ITO conductive strips (111). The ITO conductive strips (111) are formed on the substrate (10) in parallel. Each ITO conductive strip (111) has two ends and two connecting ports (112). Each connecting port (112) is formed on the end of the ITO conductive strip (111).

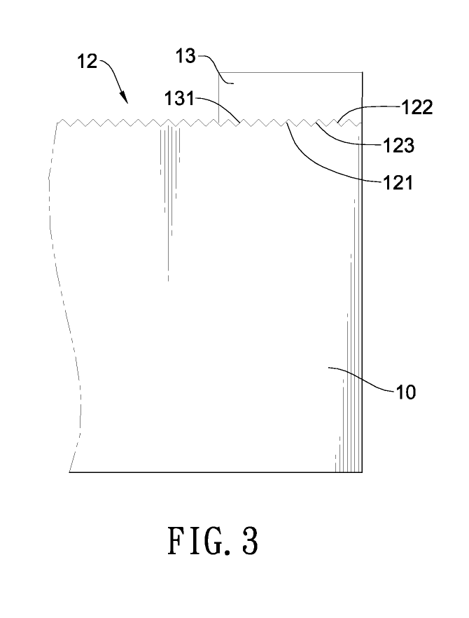

With further reference to FIGS. 2 and 3, the wire-arranged area (12) is arranged on the substrate (10) surrounding the conductive layer (11) and has a rough surface (121). The rough surface (121) is etched on the substrate (10) and has multiple protruding portions (122) and multiple concave portions (123) formed alternately. The rough surface (121) entirely covers the wire-arranged area (12).

The wires (13) are formed on the rough surface (121) of the wire-arranged area (12) by immersing the substrate (10) in metallic liquid, such as liquid silver, and electrically connecting corresponding connecting ports (112) of the conductive layer (11) to a wiring board. Each wire (13) is made of silver and has a rough bottom (131). The rough bottom (131) corresponds to the rough surface (121) of the wire-arranged area (12) and has multiple corresponding protruding portions and multiple corresponding concave portions formed alternately.

Before the wire-arranged area (12) is etched, other areas are covered with ink for protection, so the substrate (10) has multiple blank strips without ink for formation of wires (13). Then, the wire-arranged area (12) is etched. The substrate (10) is immersed into the liquid silver to form multiple wires (13), then the ink is removed.

The rough surface (121) of the wire-arranged area (12) securely engages the wires (13). Due to the concave portions (123), a thickness of each wire (13) can be increased to reduce resistance, which decreases a width of each wire (13). Furthermore, the wires (13) are formed by immersion into liquid silver after the wire-arranged area (12) has been etched, so the wires (13) have uniform width and consistent resistance. Therefore, the substrate (10) of the present invention is able to eliminate hindering issues of prior art touch panels. The touch panel with the substrate (10) of the present invention has improved quality over the prior art touch panels.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A substrate for a touch panel, comprising:
a conductive layer;
a wire-arranged area arranged on the substrate surrounding the conductive layer and having a rough surface; and
multiple wires formed on the rough surface of the wire-arranged area and each wire having a rough bottom corresponding to the rough surface of the wire-arranged area.

2. The substrate for a touch panel as claimed in claim 1, wherein
the rough surface has multiple protruding portions and multiple concave portions formed alternately; and
the rough bottom has multiple corresponding protruding portions and multiple corresponding concave portions formed alternately.

3. The substrate for a touch panel as claimed in claim 1, wherein
the rough surface is etched on the substrate to form the protruding portions and the concave portions; and
the wires are formed on the rough surface of the wire-arranged area by immersing the substrate in metallic liquid.

4. The substrate for a touch panel as claimed in claim 2, wherein
the rough surface is etched on the substrate to form the protruding portions and the concave portions; and
the wires are formed on the rough surface of the wire-arranged area by immersing the substrate in metallic liquid.

5. The substrate for a touch panel as claimed in claim 1, wherein the conductive layer is made of indium tin oxide (ITO) and each wire is made of silver.

6. The substrate for a touch panel as claimed in claim 2, wherein the conductive layer is made of indium tin oxide (ITO) and each wire is made of silver.

7. The substrate for a touch panel as claimed in claim 3, wherein the conductive layer is made of indium tin oxide (ITO) and each wire is made of silver.

8. The substrate for a touch panel as claimed in claim 4, wherein the conductive layer is made of indium tin oxide (ITO) and each wire is made of silver.

9. A touch panel, comprising at least one substrate and each substrate having
a conductive layer;
a wire-arranged area arranged on the substrate surrounding the conductive layer and having a rough surface; and
multiple wires formed on the rough surface of the wire-arranged area and each wire having a rough bottom corresponding to the rough surface of the wire-arranged area.

10. The touch panel as claimed in claim 9, wherein
the rough surface has multiple protruding portions and multiple concave portions formed alternately; and
the rough bottom has multiple corresponding protruding portions and multiple corresponding concave portions formed alternately.

11. The touch panel as claimed in claim 9, wherein
the rough surface is etched on the substrate to form the protruding portions and the concave portions; and
the wires are formed on the rough surface of the wire-arranged area by immersing the substrate in metallic liquid.

12. The touch panel as claimed in claim 10, wherein
the rough surface is etched on the substrate to form the protruding portions and the concave portions; and
the wires are formed on the rough surface of the wire-arranged area by immersing the substrate in metallic liquid.

13. The touch panel as claimed in claim 9, wherein the conductive layer is made of indium tin oxide (ITO) and each wire is made of silver.

14. The touch panel as claimed in claim 10, wherein the conductive layer is made of indium tin oxide (ITO) and each wire is made of silver.

15. The touch panel as claimed in claim 11, wherein the conductive layer is made of indium tin oxide (ITO) and each wire is made of silver.

16. The touch panel as claimed in claim 12, wherein the conductive layer is made of indium tin oxide (ITO) and each wire is made of silver.
